(19) United States
(12) Patent Application Publication
(10) Pub. No.: US 2025/0349654 A1
(43) Pub. Date: Nov. 13, 2025

(54) PACKAGE AND MANUFACTURING METHOD THEREOF

(71) Applicant: TAIWAN SEMICONDUCTOR MANUFACTURING COMPANY, LTD., Hsinchu (TW)

(72) Inventors: Ping-Yin HSIEH, Hsinchu City (TW); Pu WANG, Hsinchu City (TW); Li-Hui CHENG, New Taipei City (TW)

(73) Assignee: TAIWAN SEMICONDUCTOR MANUFACTURING COMPANY, LTD., Hsinchu (TW)

(21) Appl. No.: 18/660,154

(22) Filed: May 9, 2024

(51) Int. Cl. H01L 23/367; H01L 23/00; H01L 25/16

(52) U.S. Cl. CPC H01L 23/3675; H01L 25/16; H01L 24/16; H01L 24/29; H01L 24/32; H01L 24/33; H01L 24/73; H01L 2224/16235; H01L 2224/29124; H01L 2224/29139; H01L 2224/29144; H01L 2224/29155; H01L 2224/29166; H01L 2224/29172; H01L 2224/29181; H01L 2224/32225; H01L 2224/32245; H01L 2224/33181; H01L 2224/33183; H01L 2224/73204; H01L 2224/73253; H01L 2924/1431; H01L 2924/1432; H01L 2924/1436; H01L 2924/1437

(57) ABSTRACT

The present disclosure provides a method. In some embodiments, the method includes providing a substrate; bonding a package structure to the substrate; attaching a ring structure on the substrate and surrounding the package structure; forming a thermal interface material (TIM) layer over the package structure; attaching a heat sink structure to the TIM layer and the ring structure.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7D illustrate schematic views of intermediate stages in the formation of a package in accordance with some embodiments of the present disclosure.

FIGS. 7E-7L illustrate schematic views of packages in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present disclosure are applicable to compute-in-memory, processing-in-memory, processing-using-memory, near-memory-compute, near-data processing, near-memory processing, in-storage processing, GPU accelerator, TPU accelerator, In-memory computing, in-memory-processing, compute near memory, and/or processing near memory.

For thermal management on chip-on-wafer (CoW) system, a series of thermal interfaces is often employed, which introduces considerable thermal resistance, adversely affecting the package's ability to efficiently dissipate heat. Additionally, the use of lid-based structure in CoW system, multiple layers of thermal interface materials may be used to drive up the manufacturing costs.

Therefore, the present disclosure in various embodiments provides a method by incorporating backside metallization (BSM) on both the CoW and heat sink, and employing a ring structure instead of a lid, the number of thermal interfaces can be reduced, which in turn decreases thermal resistance, leading to enhanced thermal performance. Additionally, incorporating a metal thermal interface material (i.e., metal TIM) directly bonded to the heat sink can avoid the issues of remelting during reflow processes that can affect thermal interface material coverage and performance.

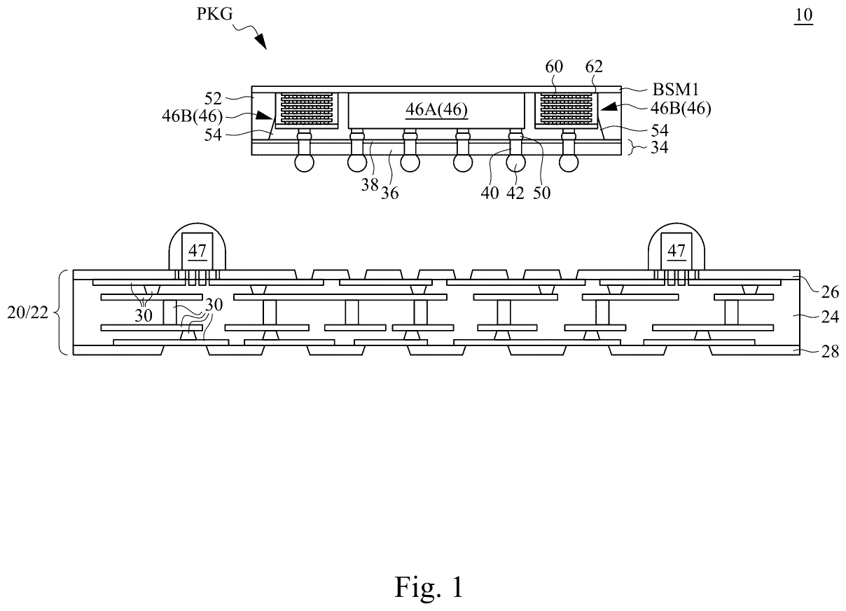

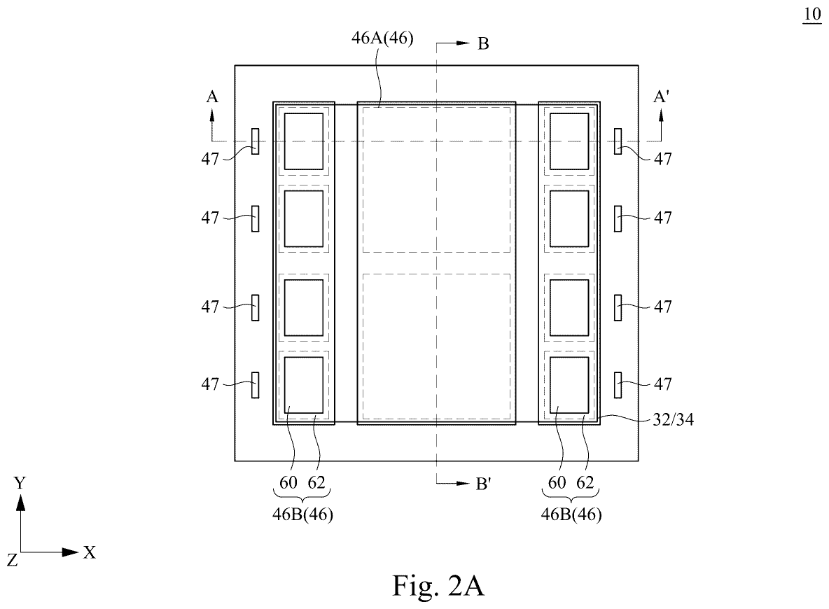

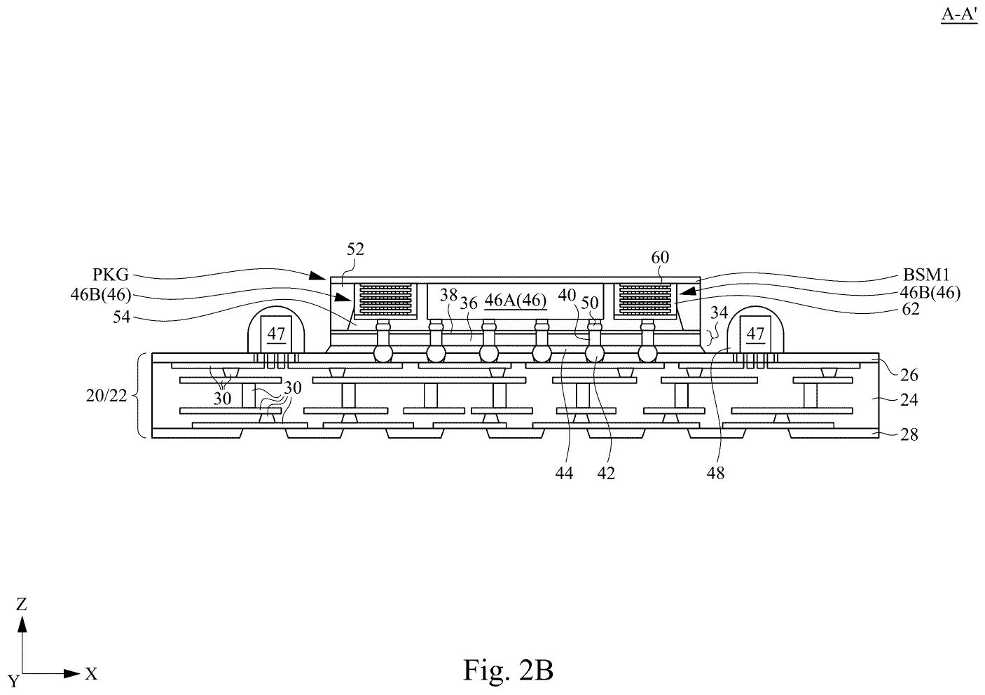

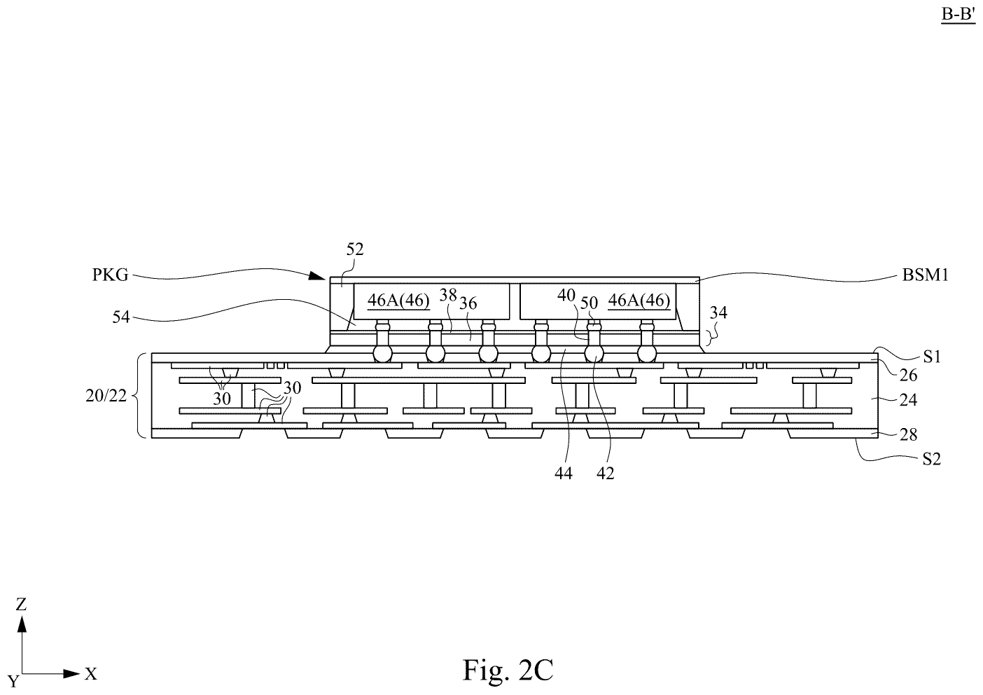

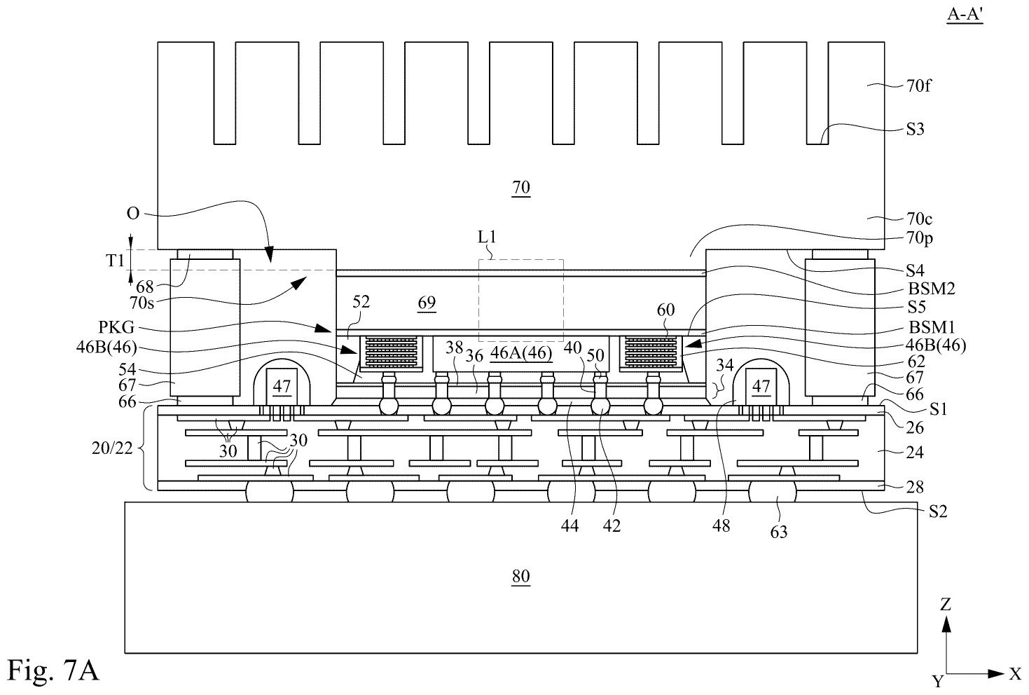

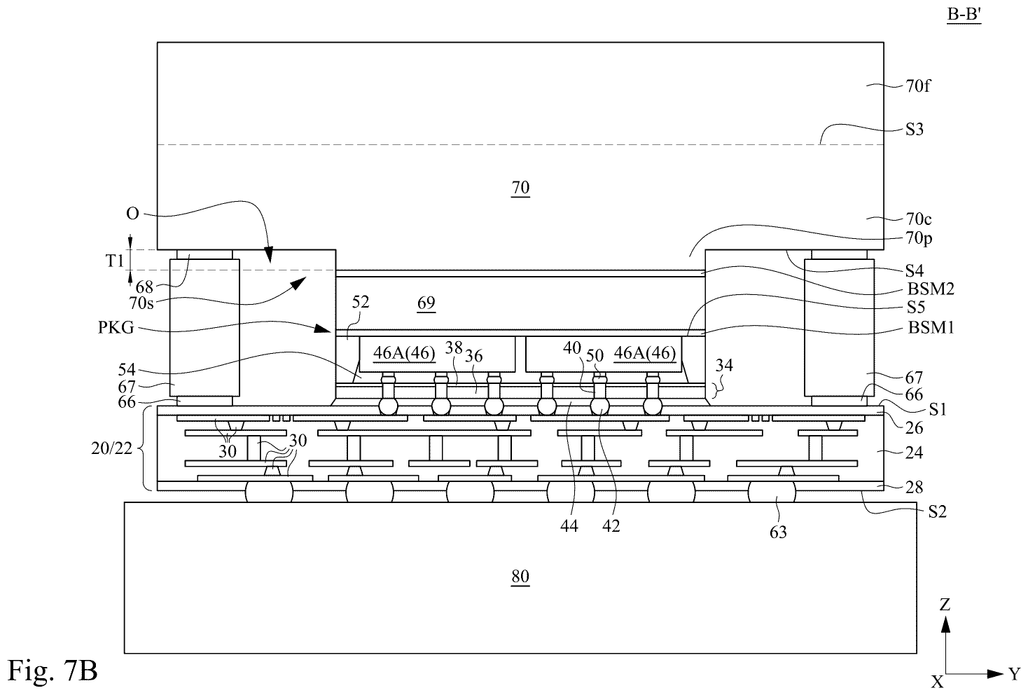

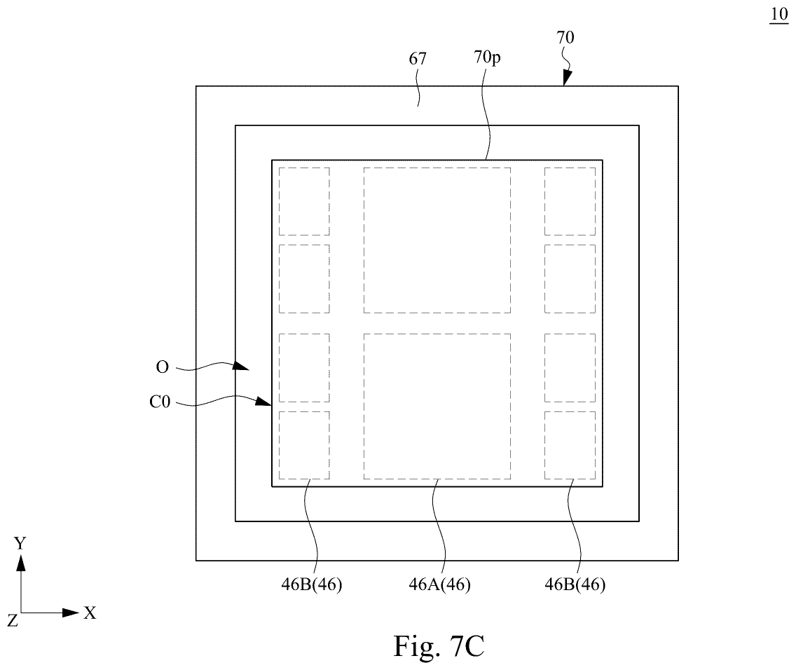

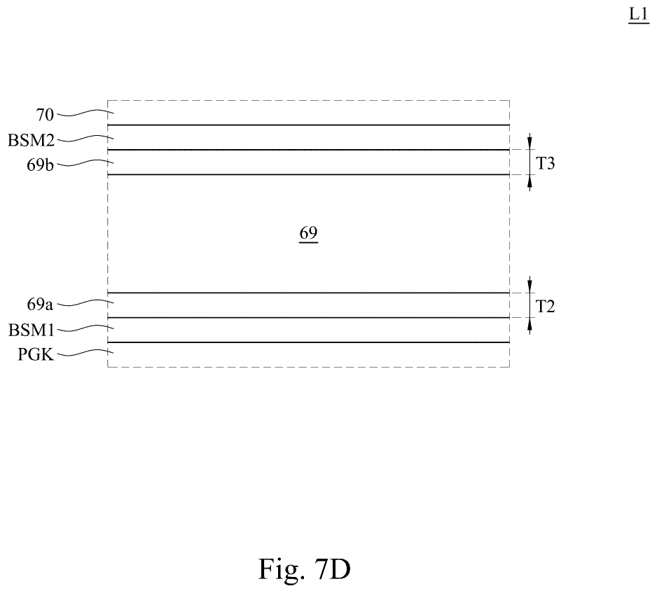

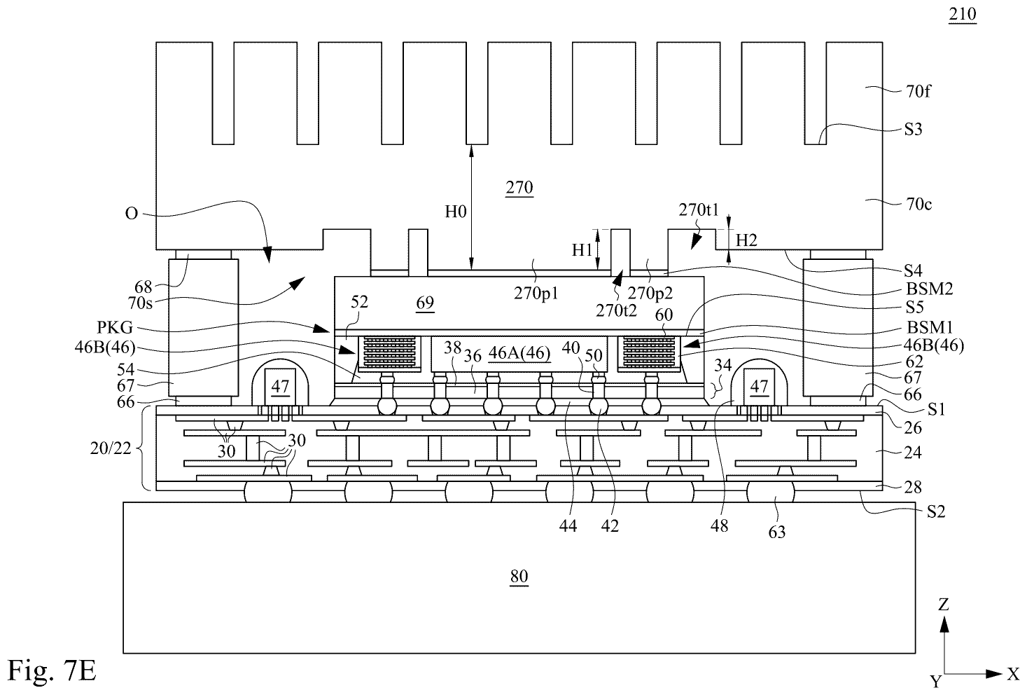

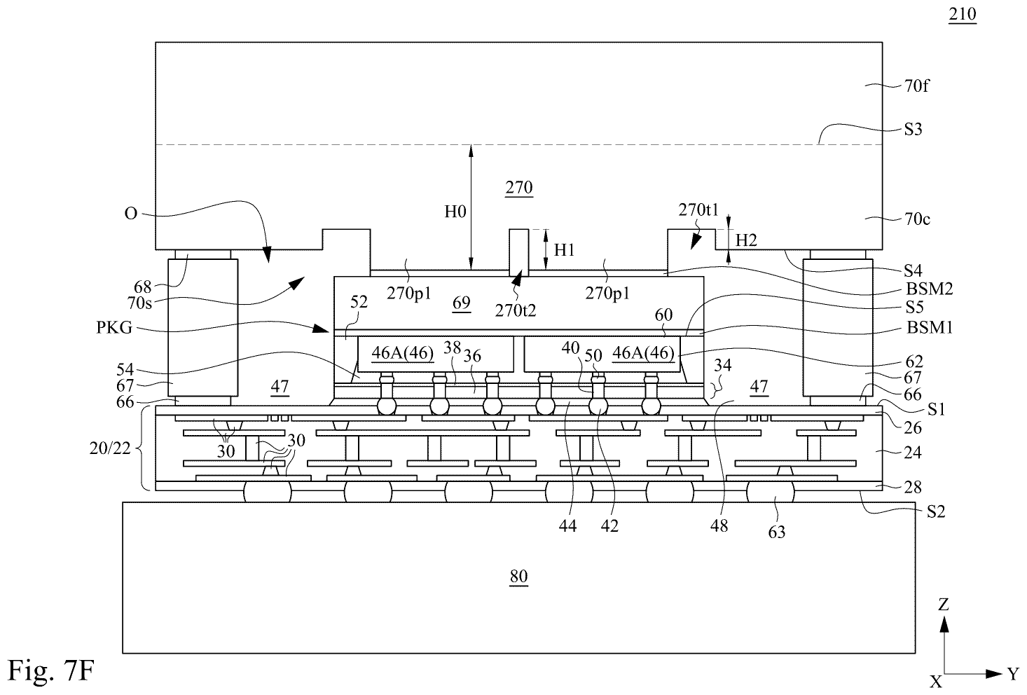

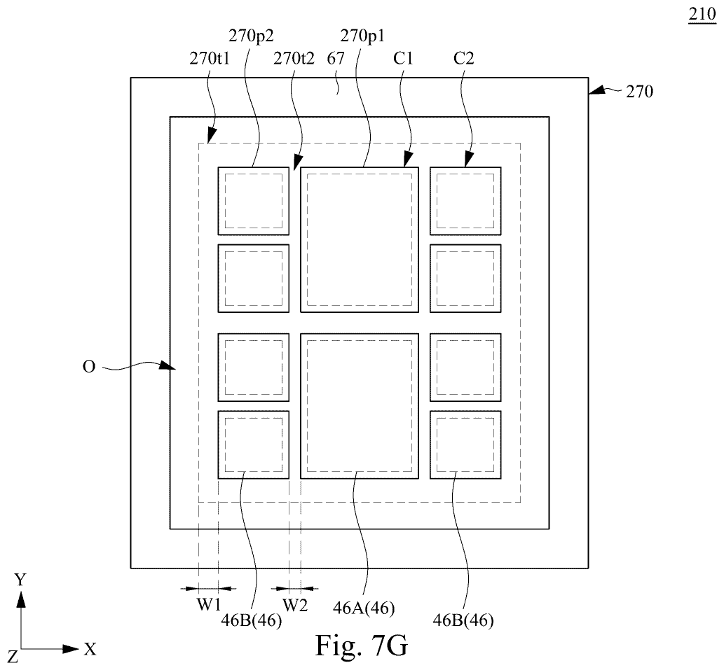

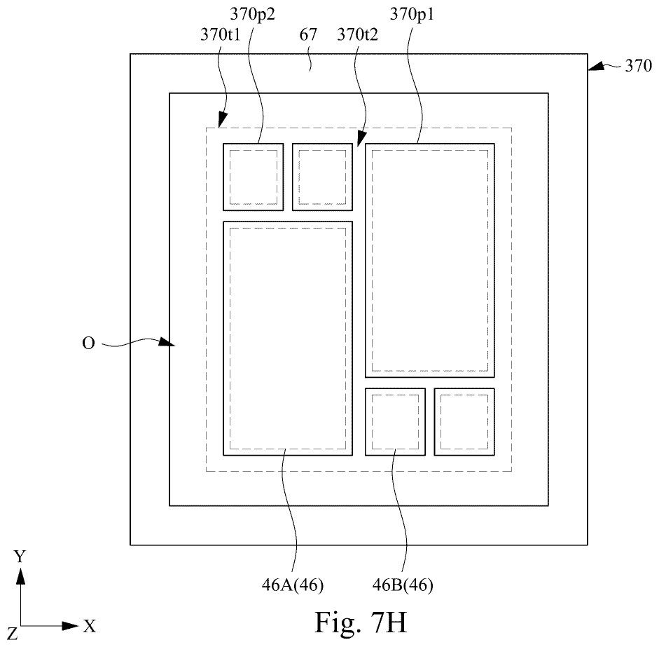

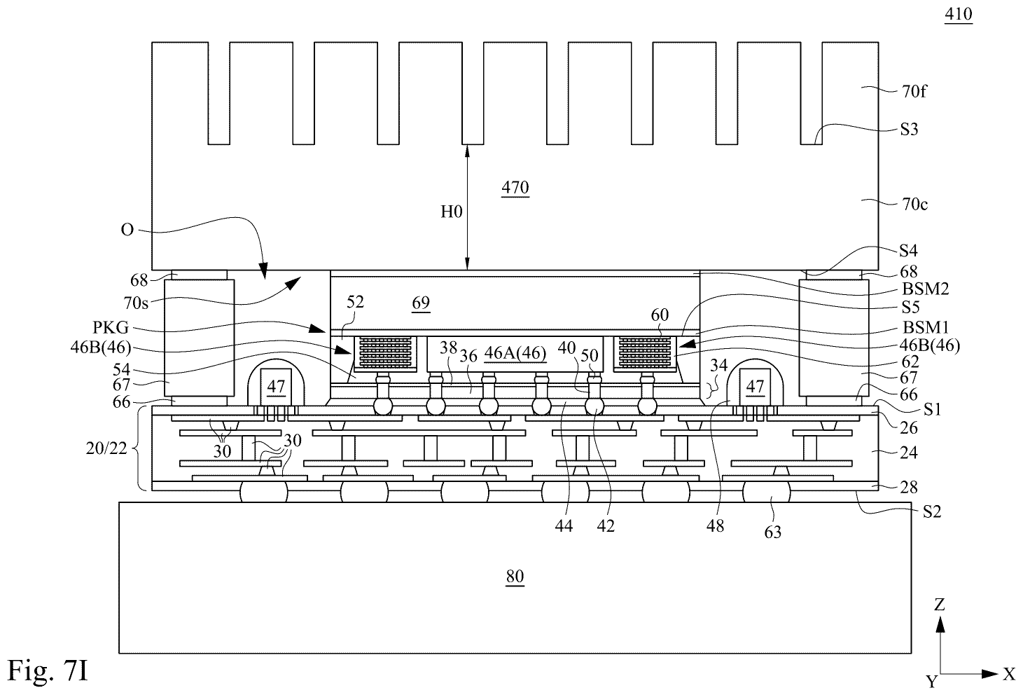

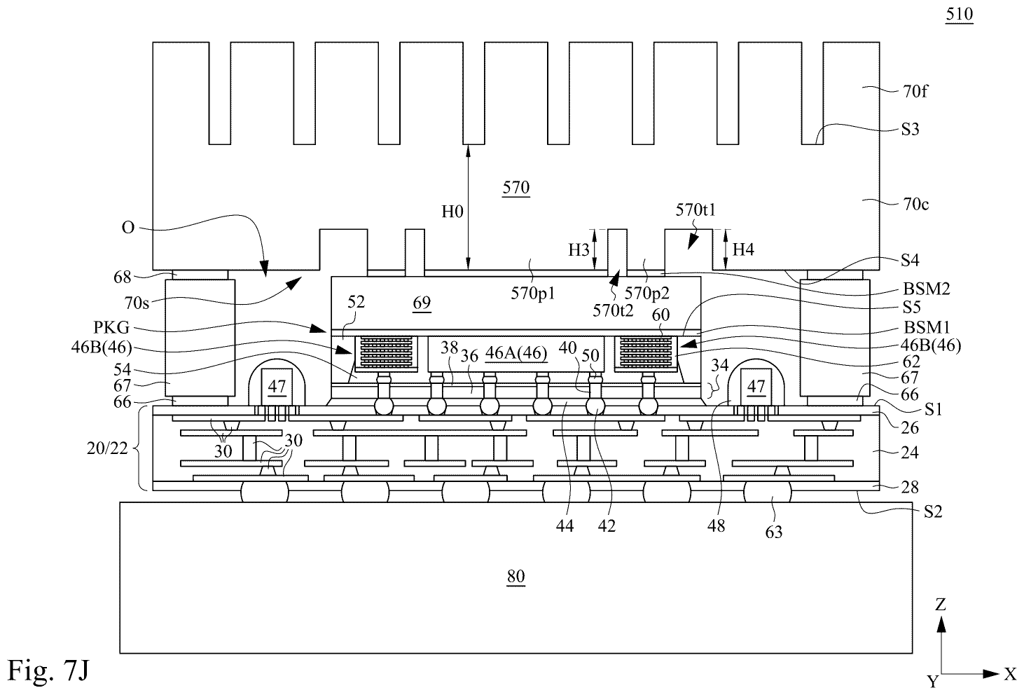

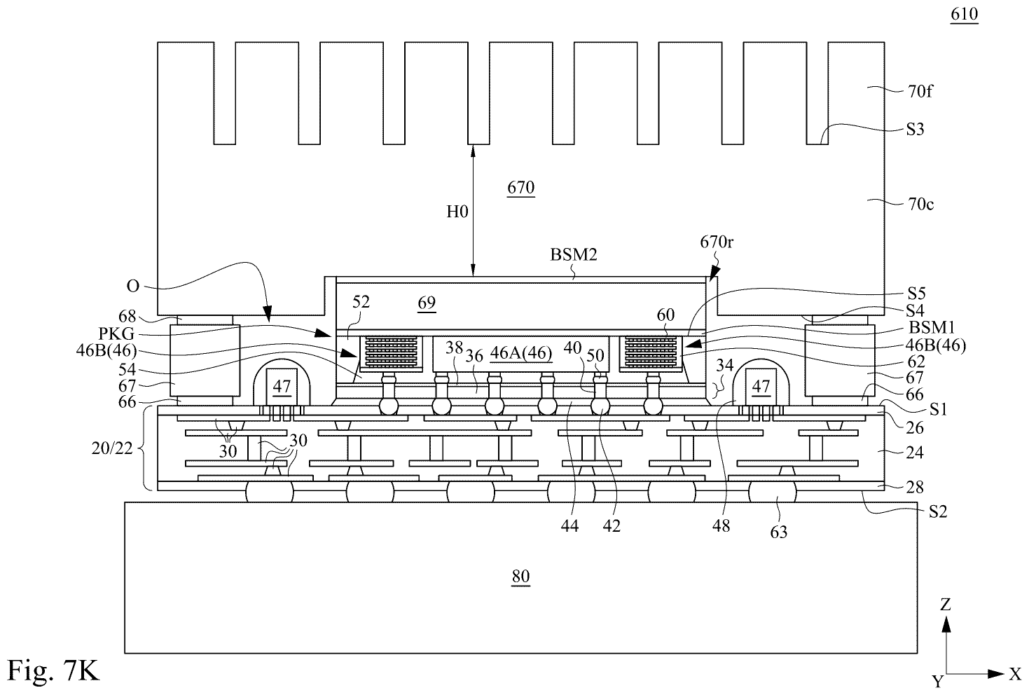

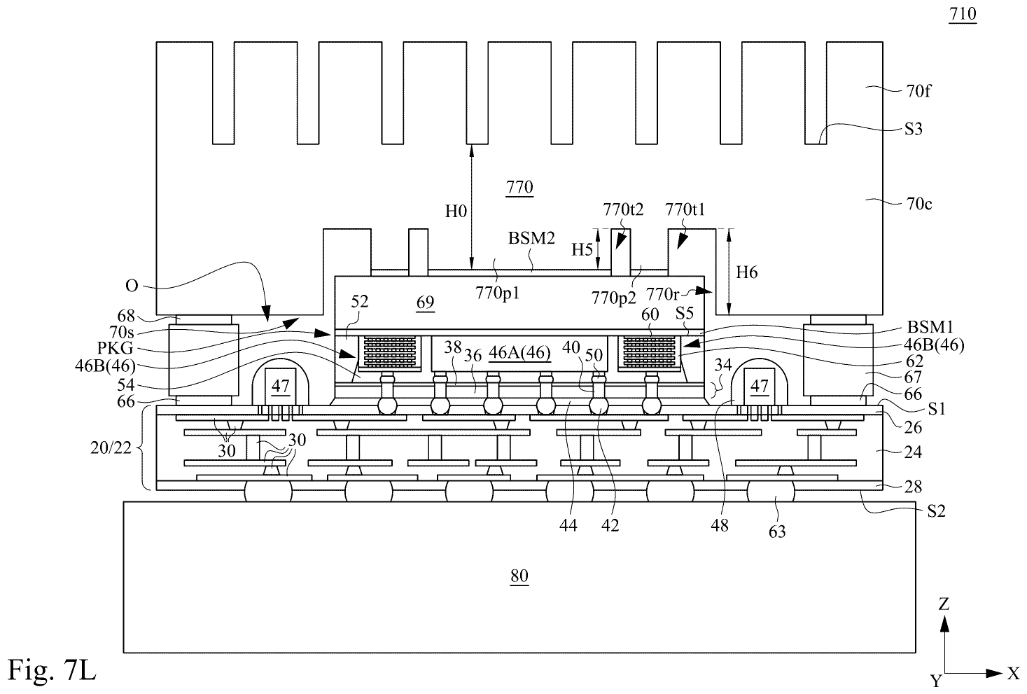

Reference is made to FIGS. 1-7D. FIGS. 1-7D illustrate schematic views of intermediate stages in the formation of a package 10 in accordance with some embodiments of the present disclosure. Specifically, FIG. 2A illustrates a top view of the package 10 in accordance with some embodiments of the present disclosure. FIGS. 1, 2B, 3, 4, 5, 6, 7A illustrate cross-sectional views of the package 10 obtained from reference cross-section A-A′ in FIG. 2A in accordance with some embodiments of the present disclosure. FIGS. 2C and 7B illustrate cross-sectional views of the package 10 obtained from reference cross-section B-B′ in FIG. 2A in accordance with some embodiments of the present disclosure. FIG. 7C illustrates a top view of the heat sink 70 and the ring structure 67 in accordance with some embodiments of the present disclosure. FIG. 7D illustrates a local enlarged view of region L1 in FIG. 7A in accordance with some embodiments of the present disclosure. It is understood that additional operations can be provided before, during, and after the processes shown by FIGS. 1-7D, and some of the operations described below can be replaced or eliminated, for additional embodiments of the method. The order of the operations/processes may be interchangeable.

Reference is made to FIGS. 1-2C. In FIG. 1, a package component 20 can be provided. The package component 20 can includes a plurality of package components 22 therein. In accordance with some embodiments, the package component 20 can be a package substrate strip, which includes a plurality of package substrates 22 therein. The package substrates 22 may be cored package substrates including cores, or may be core-less package substrates that do not have cores therein. In accordance with alternative embodiments, the package component 20 may be of another type such as an interposer wafer, a printed circuit board, a reconstructed wafer, or the like. The package component 20 may be free from (or may include) active devices such as transistors and diodes therein. Package component 20 may also be free from (or may include) passive devices such as capacitors, inductors, resistors, or the like therein.

In accordance with some embodiments of the present disclosure, the package component 20 includes a plurality of dielectric layers, which may include dielectric layers 24, a dielectric layer 26 over the dielectric layers 24, and a dielectric layer 28 under the dielectric layers 24. In accordance with some embodiments, the dielectric layers 26 and 28 may be formed of dry films such as Ajinomoto Build-up Films (ABFs). Alternatively, the dielectric layers 26 and 28 may be formed of or comprise polybenzoxazole (PBO), polyimide, benzocyclobutene (BCB), or the like, which may be coated in a flowable form and then cured. The dielectric layers 24, when being in a core, may be formed of epoxy, resin, glass fiber, prepreg (which comprises epoxy, resin, and/or glass fiber), glass, molding compound, plastic, combinations thereof, and/or multi-layers thereof. In accordance with alternative embodiments, the dielectric layers 24 may be formed of polymers such as PBO, polyimide, BCB, or the like. Redistribution lines 30, which include metal lines/pads and vias, are formed in the dielectric layers 24. The redistribution lines 30 can be interconnected to form through-connections in the package component 20. In accordance with some embodiments, when the package component 20 is not rigid enough to support itself and the overlying structure, a first carrier (not shown) can be provided to support the package component 20. In accordance with alternative embodiments, the package component 20 is thick and rigid (for example, when being a reconstructed wafer), and is able to support the structure formed thereon. Accordingly, the first carrier may not be used. The first carrier, when used, may be a glass carrier, an organic carrier, or the like. In accordance with alternative embodiments, the package component 20 can be pre-formed. In accordance with alternative embodiments, the package component 20 is built layer-by-layer over the first carrier.

Further referring to FIG. 1, package structures PKG can be placed on the package component 20. Although one package structure PKG is illustrated, a plurality of package structures PKG can be placed in this process, each being placed over a corresponding one of the package components 22. In some embodiments, the package structure PKG can be interchangeable referred to as package component or a package. The package structures PKG include device dies therein, and may include other package components such as interposers, packages, die stacks, or the like. In accordance with some embodiments, the package structures PKG can include package components 34, 46A, and 46B. In accordance with some embodiments, the package components 34 can be interposers, which can include substrates 36 and the corresponding dielectric layers 38. Accordingly, the package components 34 may also be referred to as interposers, while the package components 34 may also be of other types. The structure of the package components 34 is illustrated schematically, and the details such as the plurality of dielectric layers on the top side and bottom side of substrate 36, metal lines and vias, metal pads, or the like, are not shown. Through-substrate vias 40 can penetrate through substrate 36. The trough-substrate vias 40 can be used to interconnect the conductive features on the top side and the bottom side of substrate 36 to each other. Solder regions 42 may be underlying and joined to interposers, and are used to bond the package components 34 to package component 20. Other bonding schemes such as metal-to-metal direct bonding, hybrid bonding, or the like, may also be used for bonding the package components 34 to the package component 20.

In accordance with some embodiments, the package components 46A and 46B are bonded to the respective underlying package component 34. FIG. 1 illustrates a cross-section wherein one package component 46A and two package components 46B are visible, and are bonded to the same package component 34. Another cross-section view of the package structure PKG may be found in FIG. 2C, which shows that two package components 46A are bonded to the same package component 34 (such as an interposer). The package components 46A and 46B can be different types of package components, and are collectively referred to as package components 46. Each of the package components 46 may be a device die, a package with a device die(s) packaged therein, a System-on-Chip (SoC) die including a plurality of integrated circuits (or device dies) integrated as a system, or the like. The device dies in package components 46 may be or may comprise logic dies, memory dies, input-output dies, Integrated Passive Devices (IPDs), or the like, or combinations thereof. For example, the logic device dies in package components 46 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in package components 46 may include Static Random Access Memory (SRAM) dies, Dynamic Random Access Memory (DRAM) dies, or the like. The device dies in package components 46 may include semiconductor substrates and interconnect structures.

In the subsequent discussion in accordance with some example embodiments, the package components 46A can be referred to as device dies, which may be SoC dies in accordance with some embodiments. The package components 46B may be memory stacks such as High-Performance Memory (HBM) stacks. The package components 46B may include memory dies 60 forming a die stack, and an encapsulant 62 (such as a molding compound) encapsulating memory dies 60 therein. When viewed from top (see FIG. 2A), the encapsulant 62 may form a ring encircling the memory dies 60, and may also extend into the gaps between the memory dies 60.

Further referring back to FIG. 1, the package components 46 may be bonded to the underlying package component 34, for example, through solder regions 50. Underfills 54 can be dispensed between the package components 46 and the underlying package component 34. In some embodiments, the material of the underfill 54 can an insulating material and includes a resin (e.g., epoxy resin), a filler material, a stress release agent (SRA), an adhesion promoter, other material, or a combination thereof. In some embodiments, the underfill layer UF1 is optional. In accordance with some embodiments, the package structures PKG can be formed through a Chip-on-Wafer (CoW) bonding process, wherein the package components 46, which are discrete chips/packages, are bonded to the package components 34 that are in an unsawed wafer to form a reconstructed wafer.

After the dispensing of the underfills 54, an encapsulant such as a molding compound 52 may be applied, followed by a planarization process on the molding compound 52 to level its top surface with the top surfaces of the package components 46. In some embodiments, the molding compound 52 can be a molding compound, a molding underfill, a resin (such as epoxy resin, phenolic resin), or the like. In some alternative embodiments, the material of the molding compound 5 can include silicon oxide (SiOₓ, where x>0), silicon oxynitride (SiOₓN_{y}, where x>0 and y>0), silicon nitride (SiNₓ, where x>0), or other suitable dielectric material. In some embodiments, the molding compound 52 includes fillers. The fillers may be particles made of silica, aluminum dioxide, or the like. In some embodiments, the molding compound 52 is formed by a molding process, an injection process, a film deposition process, a combination thereof, or the like. The molding process includes, for example, a transfer molding process, a compression molding process, or the like. The film deposition process includes, for example, CVD, HDPCVD, PECVD, ALD, or combinations thereof.

Further referring back to FIG. 1, a conductive layer BSM1 can be formed on the package components 46A and 46B and the molding compound 52, and thus a reconstructed wafer can be thus formed. The conductive layer BSM1 can be in physical contact with the top surfaces of the package components 46A, the top surfaces of the package components 46B, the top surface of the molding compound 52, and the top surface of the molding compound 54. In some embodiments, the conductive layer BSM1 can include multiple metal layers, including an adhesion layer to ensure strong bond formation, a diffusion barrier layer to prevent unwanted material migration, and an anti-oxidation layer (e.g., gold) to protect against environmental damage. Specifically, the adhesion layer can be deposited on the package components 46A and 46B and the molding compound 52, ensuring that subsequent layers, such as the diffusion barrier layer, adhere well to the package components 46A and 46B and the molding compound 52. Methods such as sputtering or chemical vapor deposition (CVD) can be used for deposition of the adhesion Layer. Subsequently, the diffusion barrier layer can be deposited on top of the adhesion layer. The adhesion layer can secure the diffusion barrier layer to the package components 46A and 46B and the molding compound 52, and the diffusion barrier layer can protect the package components 46A and 46B, the molding compound 52, subsequent layers from intermixing of materials. Methods such as sputtering or chemical vapor deposition (CVD) can be used for deposition of the adhesion Layer. Subsequently, conductive and other functional layers can be deposited on top of the diffusion barrier layer. In some embodiments, the adhesion layer can include titanium (Ti), aluminum (Al), chromium (Cr), other suitable material, or any combinations thereof. In some embodiments, the diffusion barrier layer can include nickel (Ni), nickel vanadium (NiV), other suitable material, or any combinations thereof. In some embodiments, the anti-oxidation layer can include copper for conductivity or a noble metal (e.g., gold (Au)) like gold to prevent oxidation and corrosion.

However, the disclosure is not limited to. In some embodiments, the material of the conductive layer BSM1 can include metal, such as aluminum (Al), titanium (Ti), nickel (Ni), vanadium (V), tantalum (Ta), silver (Ag), and gold (Au). The thickness of the conductive layer BSM1 can be in a range from about 10 angstroms (Å) to 10,000 Å, such as about 10, 100, 1000, or 10,000 Å, allowing for flexibility in application. In some embodiments, the conductive layer BSM1 can formed by sputtering, electroplating, deposition, or dispensing process. It is noted that the conductive layer BSM1 can be utilized to promote adhesion between the subsequently formed metallic thermal interface material (TIM) layer (e.g., TIM layer 69) and the package structure PKG, and can be changeable referred to as a backside metallization or a backside metal layer.

The reconstructed wafer can be sawed apart to form the discrete package structures PKG, which can be bonded to package component 20. A singulation process is performed on the molding compound 52 and the package components 34 to obtain the package structure PKG illustrated in FIG. 1. Although only one package structure PKG is presented in FIG. 1 for illustrative purposes, those skilled in the art can understand that after the singulation process is performed, a plurality of package structures PKG can be obtained. The resulting structure of the package structures PKG is shown in FIGS. 2A-2C. In some embodiments, the singulation process typically involves dicing with a rotation blade and/or a laser beam. In other words, the singulation process includes a laser cutting process, a mechanical cutting process, a laser grooving process, other suitable processes, or a combination thereof. In some embodiments, since the package component 34 is in wafer form, the package structure PKG is considered to be formed by a chip-on-wafer process, and also the package structure PKG is referred to as a chip-on-wafer package.

After the placement of the package structures PKG onto the package component 20, the solder regions 42 can be reflowed, and an underfill 44 (see FIGS. 2B and 2C) may be dispensed to a gap between the package structures PKG and the package component 20. In some embodiments, the material of the underfill 44 is an insulating material and includes a resin (e.g., epoxy resin), a filler material, a stress release agent (SRA), an adhesion promoter, other material, or a combination thereof. In some embodiments, the underfill 44 can be optional. There may be other package components such as surface mount devices (SMDs) 47 bonding to the package component 20. In accordance with some embodiments, the surface mount devices 47 can be discrete capacitors, discrete inductors, discrete resistors, or the like. In some embodiments, no active devices such as transistors are formed in the surface mount devices 47, and the surface mount devices 47 can be changeable referred to as Independent Passive Devices (IPDs). As shown in FIG. 2A, the package structure PKG may include one or more device die(s) 46A, and a plurality of memory stacks 46B. Each of the memory stacks 46B may include stacked memory dies 60 and molding compound 62 molding (and encircling) memory dies 60. The encapsulant (for example, a molding compound) 52 can fill the spaces between neighboring the package components 46. The surface mount devices 47 may be bonded to the peripheral region of the package component 22. Additionally, a conformal coating 48 can be applied over the surface mount device 47, to safeguard against potential damage from indium migration. The conformal coating 48 can be made of polymer-based materials like acrylic or epoxy.

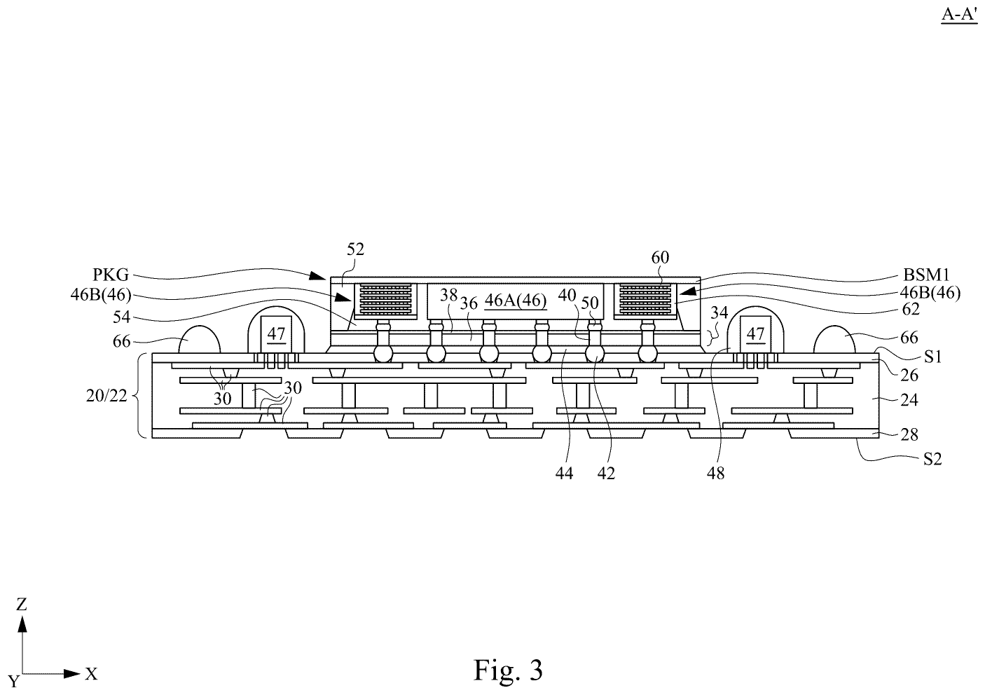

Reference is made to FIG. 3. An adhesive layer 66 can be formed on the surface S1 of the package component 20. For example, the adhesive layer 66 can be formed near edges of the surface S1 of the package component 20 to surround/encircle the package structure PKG, the underfill 44, and the surface mount devices 47. In some embodiments, the adhesive layer 66 partially covers the surface S1 of the package component 20. For example, the package structure PKG, the underfill 44, and the surface mount devices 47 are physically isolated from the adhesive layer 66. In some embodiments, the adhesive layer 66 has a ring-like shape in the plane view such as the top view. In some embodiments, the pattern of the adhesive layer 66 may be designed based on the various design. For example, the adhesive layer 66 may have a linear shape, L shape, U shape, dot shape, etc. In some embodiments, the shape of the adhesive layer 66 can depend on the shape of the package component 20. For example, when the package component 20 is in wafer form (i.e., having a circular top view), the adhesive layer 66 can exhibit a circular ring-like shape from the top view. For example, when the package component 20 is in panel form (i.e., having a rectangular or squared top view), the adhesive layer 66 can exhibit a rectangular or squared ring-like shape from the top view. In some embodiments, the adhesive layer 66 can be applied onto the package component 20 through a dispensing process, a spin-coating process, or the like. In some embodiments, the adhesive layer 66 can have a thermal conductivity greater than about 0 W/m·K to 5 W/m·K. In some embodiments, the adhesive layer 66 can include an epoxy-based material. However, the disclosure is not limited to. In some alternative embodiments, other polymeric materials having adhering property may be utilized as the adhesive layer 66.

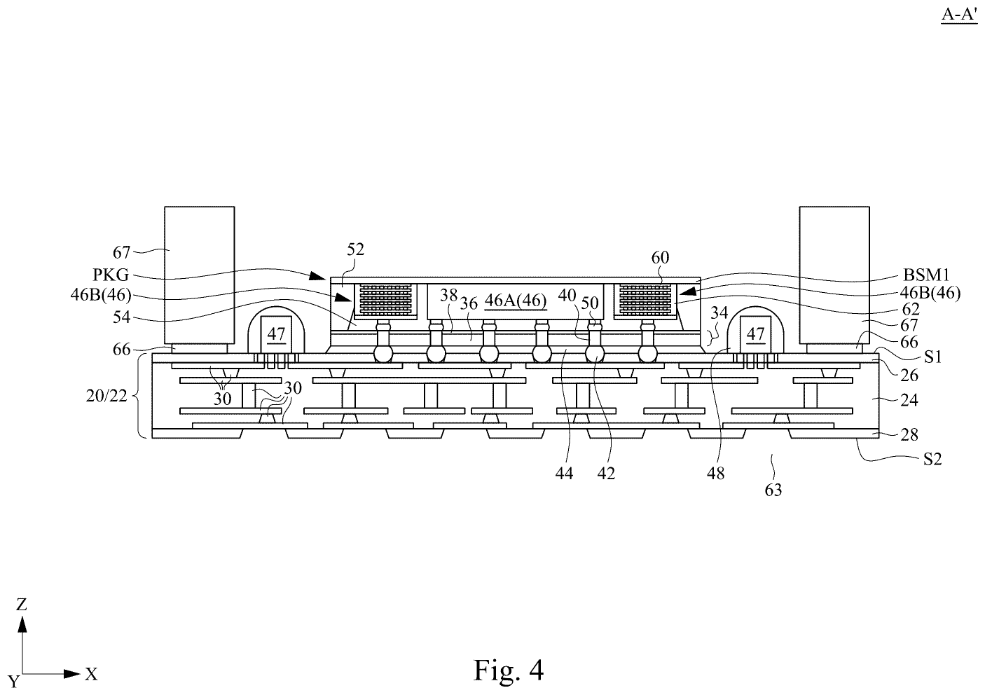

Reference is made to FIG. 4. A ring structure 67 is attached to the package component 20. In some embodiments, the ring structure 67 can be fabricated from robust materials such as stainless steel, Copper (Cu), Alloy42, among others, providing structural integrity and facilitating thermal management. In some embodiments, the ring structure 67 can be made of metal. In some embodiments, the Young's modulus of the ring structure 67 can range from about 50 GPa to about 200 GPa. In some embodiments, the ring structure 67 can encircle the package structure PKG and the surface mount devices 47. As shown in FIG. 4, the ring structure 67 can be spatially separated from the package structure PKG, the underfill 44, and the surface mount devices 47. In some embodiments, the top surface of the ring structure 67 can be located at a level height higher than the top surface of the conductive layer BSM1.

Specifically, the ring structure 67 can be attached to the package component 20 through the adhesive layer 66. For example, the ring structure 67 can be first placed over the package component 20 to be in physical contact with the adhesive layer 66. Thereafter, the ring structure 67 can be pressed against the adhesive layer 66. In some embodiments, pressing the ring structure 67 against the adhesive layer 66 may include performing a heat clamping process, wherein the process temperature of the heat clamping process ranges from about 60° C. to about 300° C. Subsequently, a curing process is performed on the adhesive layer 66 such that the ring structure 67 can be attached to the package component 20 through the adhesive layer 66. In detail, the curing process is performed on the adhesive layer 66 to securely fix the ring structure 67 onto the package component 20. In some embodiments, the process temperature of the curing process ranges from about 60° C. to about 300° C.

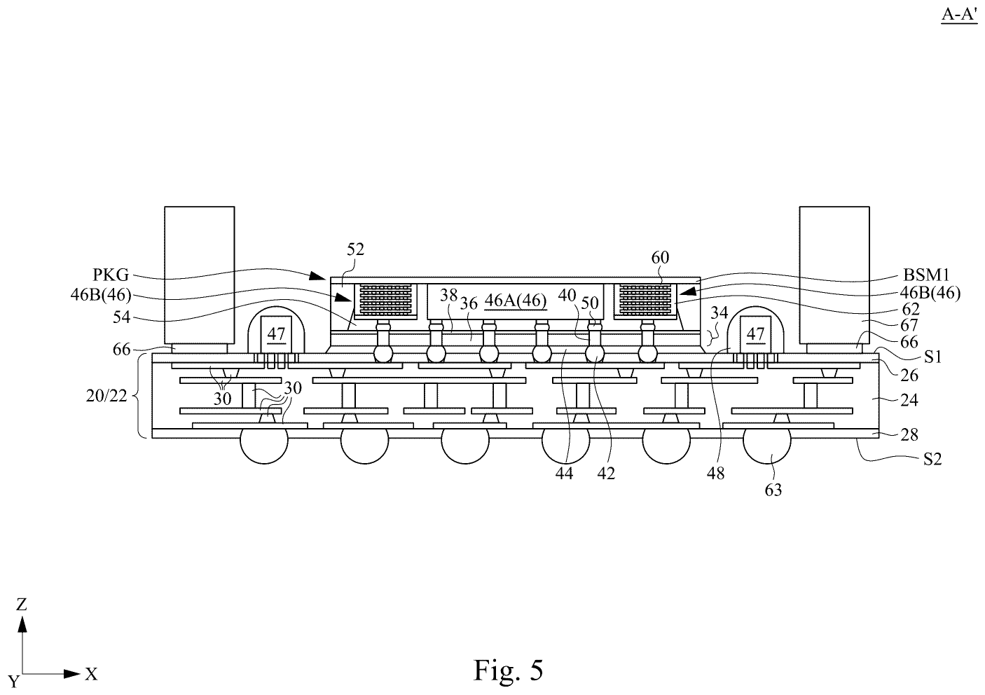

Reference is made to FIG. 5. A plurality of conductive terminals 63 can be formed on the surface S2 of the package component 20. In some embodiments, the conductive terminals 63 are solder balls, ball grid array (BGA) balls, or the like. In some embodiments, the conductive terminals 63 are made of a conductive material with low resistivity, such as Sn, Pb, Ag, Cu, Ni, Bi, or an alloy thereof. In some embodiments, the conductive terminals 63 can be in physical contact with the redistribution lines 30 (or routing patterns) exposed at the surface S2 of the package component 20. In some embodiments, the conductive terminals 63 can be used to physically and electrically connect the package component 20 to other devices, packages, connecting components, and the like. That is to say, the conductive terminals 63 can be used for providing physical and/or electrical connection to external components. As shown in FIG. 5, the conductive terminals 63 and the package structure PKG are respectively located on two opposite sides of the package component 20, where some of the conductive terminals 63 are electrically connected to the package structure PKG through the redistribution lines 30 and the solder regions 42. In some embodiments, the conductive terminals 63 can be formed on the surface S2 of the package component 20 by a ball placement process and a reflow process. In some embodiments, the reflow process may be performed to reshape the conductive terminals 63 and thus there are good physical and metallurgical connections of the conductive terminals 63 to the package component 20.

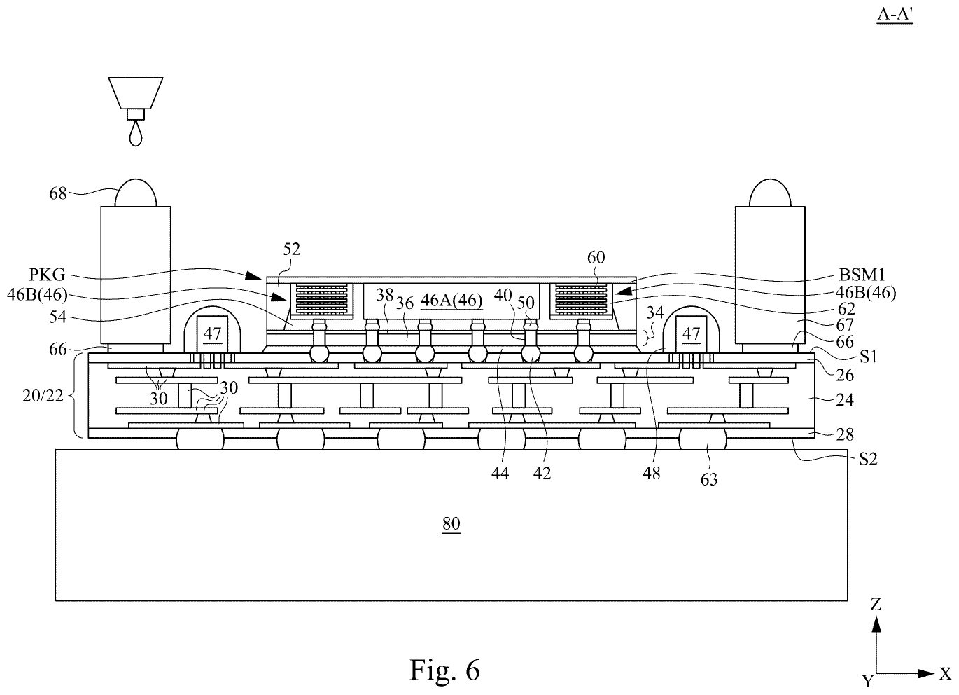

Reference is made to FIG. 6. A package component 80 can be provided. In some embodiments, the package component 80 can be a printed circuit board (PCB) or the like. In some embodiments, the package component 80 can be referred to as a circuit substrate. In some embodiments, the package component 80 can include a plurality of routing patterns embedded therein. In some embodiments, the routing patterns can be interconnected with one another. That is to say, the routing patterns can be electrically connected to one another. The package structure shown in FIG. 5 can be bonded to the package component 80. In some embodiments, the package structure shown in FIG. 5 can be attached to the package component 80 through the conductive terminals 63. For example, the conductive terminals 63 of the package structure shown in FIG. 5 can be in physical contact with the routing patterns exposed at the surface of the package component 80 to render electrical connection between the package structure shown in FIG. 5 and the package component 80.

Subsequently, the adhesive layer 68 can be disposed on the top surface of the ring structure 67 to surround/encircle the package structure PKG, the underfill 44, and the surface mount devices 47. In some embodiments, the adhesive layer 68 can have a ring-like shape in the plane view such as the top view. In some embodiments, the pattern of the adhesive layer 68 may be designed based on the various design. For example, the adhesive layer 68 may have a linear shape, L shape, U shape, dot shape, etc. In some embodiments, the shape of the adhesive layer 68 can depend on the shape of the package component 20. For example, when the package component 20 can be in wafer form (i.e., having a circular top view), the adhesive layer 68 can exhibit a circular ring-like shape from the top view. For example, when the package component 20 can be in panel form (i.e., having a rectangular or squared top view), the adhesive layer 68 can exhibit a rectangular or squared ring-like shape from the top view. In some embodiments, the adhesive layer 68 can be applied onto the ring structure 67 through a dispensing process, a spin-coating process, or the like. In some embodiments, the adhesive layer 68 can have a thermal conductivity lower than about 0.5 W/m·K. In some embodiments, the adhesive layer 68 can include an epoxy-based material. However, the disclosure is not limited to. In some alternative embodiments, other polymeric materials having adhering property may be utilized as the adhesive layer 68.

Reference is made to FIGS. 7A-7D. A TIM layer 69 can be formed on the conductive layer BSM1. In some embodiments, the TIM layer 69 can be in sheet type. In some embodiments, the TIM layer 69 can be formed on the conductive layer BSM1 through a pick-and-place process. In some embodiments, the material of the TIM layer 69 can be soldered type material. In some embodiments, the TIM layer 69 can be formed by purely metallic materials and can be interchangeable referred to as a metal thermal interface material. In some embodiments, the TIM layer 69 can be free of organic material and polymeric material. In some embodiments, the material of the TIM layer 69 includes a metallic material, such as indium, copper, tin, InAg or a combination thereof. In some embodiments, the thermal conductivity of the TIM layer 69 ranges from about 10 W/(m·K) to about 90 W/(m·K). In some embodiments, the Young's modulus of the TIM layer 69 ranges from about 5 GPa to about 70 GPa. In some embodiments, the top surface of the TIM layer 69 can be located at a level height lower than that of the top surface of the ring structure 67. However, the disclosure is not limited to. In some alternative embodiments, the top surface of the TIM layer 69 can be located at a level height higher than that of the top surface of the ring structure 67.

In some embodiments, the TIM layer 69 can be overlapped with the package components 46A and 46B. For example, the vertical projection of the TIM layer 69 onto the package component 20 can be completely overlapped with the vertical projection of the package components 46A and 46B onto the package component 20. However, the disclosure is not limited to. In some alternative embodiments, the vertical projection of the TIM layer 69 onto the package component 20 can be partially overlapped with the vertical projection of the package components 46A and 46B onto the package component 20. From another point of view, the TIM layer 69 can be at least formed to be corresponded to the location of the package components 46A and 46B (see FIGS. 7E, 7F, 7J, and 7L).

In some embodiments, for better adhesion, a flux (not shown) can be disposed between the conductive layer BSM1 and the TIM layer 69, and another flux (not shown) can be applied onto the top surface of the TIM layer 69. For example, before the TIM layer 69 can be placed on the conductive layer BSM1, a flux (not shown) can be formed over the conductive layer BSM1; and after the TIM layer 69 can be placed on the conductive layer BSM1, another flux (not shown) can be formed on the top surface of the TIM layer 69. In some embodiments, the formation of the flux includes performing a jetting process or a dispensing process. In some embodiments, the material of the flux includes rosin or acids.

Referring back to FIGS. 7A-7D, the heat sink 70 can be placed over the ring structure 67, the package component 20, the package structure PKG, and the surface mount devices 47, such that the package structure PKG and the TIM layer 69 can be located between the package component 20 and the heat sink 70. The heat sink 70 can serve the function of heat dissipation. In other words, the heat generated during operation of the package structure PKG may be dissipated through the path created by the heat sink 70. The heat sink 70, the ring structure 67, and the package component 20 together enclose the package structure PKG and the surface mount devices 47. In other words, the heat sink 70 and the ring structure 67 can be formed to accommodate the package structure PKG and/or the surface mount devices 47. For example, cover portion 70c of the heat sink 70 and the ring structure 67 may exhibit an upside down U-shape in a cross-sectional view, as shown in FIGS. 7A and 7B. In some embodiments, the heat sink 70 can be made of metal, plastic, ceramics, or the like. The metal for the heat sink 70 may include, but not limit to, copper, stainless steel, solder, gold, nickel, molybdenum, NiFe or NiFeCr. In some embodiments, the thermal conductivity of the lid structure 70 ranges from about 80 W/(m·K) to about 450 W/(m·K). In some embodiments, the Young's modulus of the lid structure 70 ranges from about 50 GPa to about 200 GPa.

In some embodiments, the heat sink 70 can include a cover portion 70c, a protruding portion 70p, and fin portions 70f. The cover portion 70c can extend along the direction X and the direction Y and can be in sheet type. The fin portions 70f can upwardly protrude from a surface S3 the cover portion 70c. The protruding portion 70p protrude out from a surface S4 (or back-side surface) of the cover portion 70c opposite to the surface S3. In some embodiments, the protruding portion 70p can be thicker than the adhesive layer 68. By way of example and not limitation, the thickness T1 of the protruding portion 70p can be in a range from about 50 to about 100 μm, such as 50, 60, 70, 80, 90, or 100 μm. In other words, the protruding portion 70p with the cover portion 70c can form a stepped structure 70s on the back-side of the heat sink 70, positioned over the CoW area. This stepped structure 70s can be tailored to match the height of the ring structure 67, ensuring a fit and an optimized thermal interface. However, not all embodiments feature this stepped structure, allowing for flexibility in application. In some embodiments, the cover portion 70c can be interchangeable referred to as a bulk portion, and the fin portion can be interchangeable referred to as heat dissipating fins.

In some embodiments, the cover portion 70c and the protruding portion 70p can be integrally formed. For example, the material of the protruding portion 70p can be the same as the material of the cover portion 70c. However, the disclosure is not limited thereto. In some alternative embodiments, the protruding portion 70p may be installed on the cover portion 70a. For example, the material of the protruding portion 70p may be different from the material of the cover portion 70c. In some embodiments, the cover portion 70c and the fin portions 70f can be integrally formed. For example, the material of the fin portions 70f can be the same as the material of the cover portion 70c. However, the disclosure is not limited thereto. In some alternative embodiments, the fin portions 70f may be installed on the cover portion 70c. For example, the material of the fin portions 70f may be different from the material of the cover portion 70c.

The heat sink 70 can be securely fixed onto the ring structure 67 through attaching the cover portion 70c to the adhesive layer 68, such that the protruding portion 70p can extend into the opening O of the ring structure 67. In some embodiments, the contour C0 (see FIG. 7C) of the protruding portion 70p can be substantially corresponding to the contour of the opening O of the ring structure 67 (see FIG. 7C). Therefore, the TIM layer 69 can be sandwiched between the protruding portion 70p of the lid structure 70 and the package structure PKG.

In some embodiments, prior to the attachment of the lid structure 70, a conductive layer BSM2 can be formed on the protruding portion 70p of the heat sink 70. In detail, as illustrated in FIGS. 7A and 7B, the conductive layer BSM2 and the protruding portion 70p are disposed in the opening O of the ring structure 67. It is noted that the conductive layer BSM2 can be utilized to promote adhesion between the TIM layer 69 and the heat sink 70, and can be referred to as a backside metallization or a backside metal layer. In some embodiments, the material of the conductive layer BSM2 can be the same as the material of the conductive layer BSM1. In alternative some embodiments, the material of the conductive layer BSM2 can be different from the material of the conductive layer BSM1. In some embodiments, the conductive layer BSM2 can be formed on the heat sink 70 through a plating, sputtering or dispensing process. In some embodiments, the material of the conductive layer BSM2 can include metal, such as Al, Ti, Ni, V, Au, Ag or Cu. In some embodiments, the conductive layer BSM2 can be integrated as an Au plated heat sink. That is, the back-side of the heat sink 70 can be coated with gold (Au) to improve thermal conductivity and resist oxidation, while its bulk composition may include materials like copper (Cu) or aluminum (Al). The heat sink is bonded to both the CoW and the ring structure 67 using an adhesive, ensuring a secure and thermally efficient assembly.

Specifically, after the conductive layer BSM2 can be formed on the heat sink 70, the heat sink 70 and the conductive layer BSM2 can be placed above the TIM layer 69 and the adhesive layer 68, such that the conductive layer BSM2 can be in physical contact with the top surface of the TIM layer 69, and the cover portion 70a of the heat sink 70 can be in physical contact with the adhesive layer 68. Thereafter, the heat sink 70 and the conductive layer BSM2 are pressed against the TIM layer 69. However, the disclosure is not limited thereto. In some alternative embodiments, there is no conductive layer BSM2 formed on the heat sink 70.

In some embodiments, pressing the heat sink 70 and the conductive layer BSM2 against the TIM layer 69 and the adhesive layer 68 may include performing a heat clamping process, wherein the process temperature of the heat clamping process ranges from about 60° C. to about 300° C. Subsequently, a curing process can be performed on the adhesive layer 68 such that the heat sink 70 can be attached to the package component 20 through the adhesive layer 68. In detail, the curing process can be performed on the adhesive layer 68 to securely fix the heat sink 70 onto the package component 20. In some embodiments, the process temperature of the curing process ranges from about 60° C. to about 300° C. However, the disclosure is not limited to. In some embodiments, during the curing process, the cover portion 70c can be attached to the package structure PKG through the protruding portion 70p and the TIM layer 69 attached thereto. That is to say, in such embodiments, during the curing process, there is a good physical and metallurgical connection of the heat sink 70 to the package structure PKG. In such embodiments, the process temperature of the curing process ranges from about 160° C. to about 260° C.

Therefore, the package of the present disclosure can incorporate a CoW assembly (e.g., the package structures PKG) enhanced with the conductive layer BSM1 (e.g., backside metallization layer) on its rear surface S5, the TIM layer 69, the ring structure 67, and the heat sink 70, also featuring the conductive layer BSM2 (e.g., backside metallization layer) on its backside. This assembly can be arranged sequentially to optimize thermal management. Within this configuration, there are two interfaces: the first interface between the heat sink 70 and the TIM layer 69, and the second interface between the TIM layer 69 and the package structure PKG (e.g., CoW).

A backside metallization (BSM) process can be applied to the back-side of the heat sink 70, in conjunction with a ring process that can eliminate the application of a lid on the CoW. This approach can enable a direct bond between the TIM layer 69 and the heat sink 70, effectively reducing the total number of thermal interfaces. This reduction can enhances thermal efficiency, achieving at least about 50% decrease in thermal resistance (TR), such as about 50, 55, 60, 65, 70, 75, 76.8, 80%. By way of example and not limitation, the first interface can exhibit the thermal resistance in a range from about 0.8 to 1 mm² K/W, such as about 0.8, 0.85, 0.9, 0.95, or 1 mm² K/W. The TIM layer 69 can exhibit a bulk thermal conductivity of about 1 to 5 mm² K/W, such as about 1, 1.5, 2, 2.3, 2.5, 3, 3.5, 4, 4.5, or 5 mm² K/W. The second interface can exhibit the thermal resistance of about 0.8 to 1 mm² K/W, such as about 0.8, 0.85, 0.9, 0.95, or 1 mm² K/W.

By integrating the ring structure 67 and backside metallization processes into the package and utilizing TIM layer 69 directly bonded to the heat sink 70, such that the heat dissipation can be improved. It can simplify the thermal pathway, leading to a decrease in overall thermal resistance from about 17.7 to about 4.4 mm² K/W, which signifies a reduction of at least about 50% in thermal resistance.

In some embodiments, at the junctures within semiconductor packages, where the TIM layer 69 interfaces with the conductive layer BSM2 and come into contact with the heat sink 70, a series of intermetallic compounds (IMCs) can be synthesized to form an intermetallic compound layer 69b. In some embodiments, a series of intermetallic compounds can also be synthesized to form an intermetallic compound layer 69a at a side of the TIM layer 69 adjacent to the conductive layer BSM1. The formation of the intermetallic compound can enhance the package's performance. The intermetallic compound can include but not limited to alloys of gold-indium (Au—In), nickel-indium (Ni—In), nickel-gold-indium (Ni—Au—In), other suitable material or combinations thereof. Specifically, the intermetallic compound can have a robust metallurgical bond. The intermetallic compound layer 69b can ensure that the bond between the TIM layer 69 and both the conductive layer BSM2 and the heat sink 70 can be mechanically strong for the long-term reliability of the semiconductor device, as it may endure various thermal cycles and mechanical stresses without degradation. Similarly, the intermetallic compound layer 69a can ensure that the bond between the TIM layer 69 and both the conductive layer BSM1 and the package PKG can be mechanically strong for the long-term reliability of the semiconductor device, as it may endure various thermal cycles and mechanical stresses without degradation. Additionally, the intermetallic compound can contribute to the thermal pathway from the semiconductor device to the heat sink 70, facilitating efficient heat transfer.

In some embodiments, the formation of the intermetallic compound of the intermetallic compound layer 69b can occur over a range of thicknesses T3, spanning from about 0.1 to 2 μm, such as about 0.1, 0.5, 0.8, 1, 1.5, 1.8, or 2 μm. If the thickness of the intermetallic compound formation of the intermetallic compound layer 69b is less than about 0.1 μm, the intermetallic compound formation may not provide adequate mechanical support or thermal conduction for the semiconductor package. If the thickness of the intermetallic compound formation of the intermetallic compound layer 69b is greater than about 2 μm, the intermetallic compound formation may introduce unnecessary thermal resistance or compromise the integrity of the bond. In some embodiments, the formation of the intermetallic compound of the intermetallic compound layer 69a can occur over a range of thicknesses T2, spanning from about 0.1 to 2 μm, such as about 0.1, 0.5, 0.8, 1, 1.5, 1.8, or 2 μm. If the thickness of the intermetallic compound formation of the intermetallic compound layer 69a is less than about 0.1 μm, the intermetallic compound formation may not provide adequate mechanical support or thermal conduction for the semiconductor package. If the thickness of the intermetallic compound formation of the intermetallic compound layer 69a is greater than about 2 μm, the intermetallic compound formation may introduce unnecessary thermal resistance or compromise the integrity of the bond.

Reference is made to FIGS. 7E-7G. FIGS. 7E and 7F illustrate cross-sectional views of a package 210 including a heat sink 270 corresponding to FIGS. 7A and 7B, respectively, in accordance with some embodiments of the present disclosure. FIG. 7G illustrates a top view of the heat sink 270 and the ring structure 67 in accordance with some embodiments of the present disclosure. While FIGS. 7E-7G illustrate embodiments of the package 210 with a different heat sink configuration than the package 10 in FIGS. 1-7D, the present disclosure may repeat reference numerals and/or letters in the various examples. This repetition is for the purpose of simplicity and clarity and does not in itself dictate a relationship between the various embodiments and/or configurations discussed.

In some embodiments, voids may generate within the TIM layer 69 or around the heat sink 70 in semiconductor package, which in turn impacts the thermal performance of the package. These voids can be air gaps that form during the assembly process, including solder reflow, thermal interface material application, or when the package undergoes thermal cycling. In some embodiments, the voids can be generated due to outgassing of solvents or fluxes. The voids can act as thermal insulators due to the low thermal conductivity of air, reducing the overall effectiveness of heat dissipation from the semiconductor device to the heat sink 70. Additionally, the voids can compromise the mechanical bond between the TIM layer 69 and the heat sink 70, reducing the structural integrity of the package and making it more susceptible to delamination or failure during thermal cycling.

Therefore, at least one trench (e.g., trenches 270t1, 270t2 as shown in FIGS. 7E-7G) can be formed on the back-side of the heat sink 270 to mitigate the impact of the voids. The trench formed on the back-side of the heat sink 270 can act as a reservoir to trap outgassing materials, flux, and air that would otherwise form voids within the interface areas. By providing the trenches 270t1 and 270t2 for the voids to escape to, the formation of voids within the TIM layer 69 or between the TIM layer 69 and the heat sink 270 can be minimized. By reducing the presence of the voids, the trenches 270t1 and 270t2 can improve thermal conductivity across the interface, resulting in more efficient heat dissipation and longer device lifespans. In some embodiments, the trenches 270t1 and 270t2 formed on the back-side of the heat sink 270 can be interchangeable referred to as an empty space.

The heat sink 270 can include a cover portion 70c, distinct protruding portions 270p1 and 270p2, and fin portions 70f. The protruding portions 270p1 and 270p2 extend from the surface S4 of the cover portion 70c, which is the opposite side to the surface S3, ensuring a mechanical fit and enhanced thermal coupling with the package components 46A and 46B beneath. The thickness of protruding portions 270p1 and 270p2 may surpass that of the adhesive layer 68. Specifically, contours C1 and C2 (see FIG. 7G) of the protruding portions 270p1 and 270p2 can be aligned with the geometries of the package components 46A and 46B within the package structure PKG. In some embodiments, the spatial footprint of the package component 46A can fit within the boundary of the protruding portion 270p1, and similarly, the footprint of package component 46B can fit within the boundary of protruding portion 270p2. In some embodiments, the spatial footprint of the protruding portion 270p1 can fit within the boundary of the package component 46A, and similarly, the footprint of the protruding portion 270p2 can fit within the boundary of the package component 46B.

Furthermore, the placement of trenches 270t1 and 270t2 within the heat sink 270, associated with the protruding portions 270p1 and 270p2, can target areas within the package structure PKG that are less involved in heat generation. Specifically, the trench 270t1 can be positioned to align with the molding compound 52, while the trench 270t2 can be positioned to align with the underfill 54, nestled between the package components 46A and 46B. In some embodiments, the trench 270t1 can be with a ring-shaped footprint, encircling the areas of the package. In some embodiments, a width W1 (see FIG. 7G) of trench 270t1 can be larger than a width W2 (see FIG. 7G) of trench 270t2.

In the heat sink 270, the collective structure formed by the cover portion 70c alongside the protruding portions 270p1 and 270p2 can establish a vertical dimension (e.g., thickness/height) H0. Within this collective structure, two distinct trenches 270t1 and 270t2 can have their own depths H2 and H1, respectively. The depth H1 also can correspond to the vertical dimension of the protruding portions 270p1 and 270p2. In some embodiments, the vertical dimension H0 can be greater than the depth H1 of trench 270t2, and the depth H1 of trench 270t2 can be equal to or greater than the depth H2 of trench 270t1. This gradation in dimensions can ensure a tailored fit and optimized thermal pathway within the heat sink 270, allowing for efficient heat dissipation.

Reference is made to FIG. 7H. FIG. 7H illustrates a top view of the heat sink 370 in accordance with some embodiments of the present disclosure. While FIG. 7H illustrates embodiments of a different heat sink configuration than the package 210 in FIGS. 7E-7G, the present disclosure may repeat reference numerals and/or letters in the various examples. This repetition is for the purpose of simplicity and clarity and does not in itself dictate a relationship between the various embodiments and/or configurations discussed.

As shown in FIG. 7H, the difference between the embodiment in FIG. 7H and the embodiment in FIGS. 7E-7G is in that the altered arrangement and quantity of the protruding portions 370p1 and 370p2, which differ from their counterparts (e.g., protruding portions 270p1 and 270p2) in the previous illustrations. This adjustment is to enhance the alignment of the protruding portions 370p1 and 370p2 with the package components 46A and 46B situated within the package structure PKG beneath them, ensuring that each protruding portions 370p1 and 370p2 can overlay the corresponding package components 46A and 46B, which in turn allows for optimizing thermal conduction pathways and ensuring robust mechanical support, thereby enhancing the overall performance and reliability of the semiconductor package.

Furthermore, despite these alterations in the protruding portions 370p1 and 370p2, the placement of the trenches 370t1 and 370t2 remain consistent with the earlier embodiment. Specifically, the trench 370t1 can be positioned to align with the molding compound 52, while the trench 370t2 can be positioned to align with the underfill 54, nestled between the package components 46A and 46B. In some embodiments, the trench 370t1 can be with a ring-shaped footprint, encircling the areas of the package.

Reference is made to FIG. 7I. FIG. 7I illustrates a cross-sectional view of a package 410 corresponding to FIG. 7A in accordance with some embodiments of the present disclosure. While FIG. 7I illustrates embodiments of the package 410 with a different heat sink configuration than the package 10 in FIGS. 1-7D, the present disclosure may repeat reference numerals and/or letters in the various examples. This repetition is for the purpose of simplicity and clarity and does not in itself dictate a relationship between the various embodiments and/or configurations discussed.

As shown in FIG. 7I, the difference between the embodiment in FIG. 7I and the embodiment in FIGS. 1-7D is in that while the heat sink 470 retains a cover portion 70c and fin portions 70f, akin to the previous embodiment, it eliminates the protruding portion 70p present in the previous embodiment. That is, the bottom surface S4 of the heat sink 470 can be a flat surface. The heat sink 470 can represent a streamlined approach to the heat sink architecture, focusing on the essential elements necessary for effective thermal management. The cover portion 70c can serve as the interface between the heat sink 470 and the package structure PKG, facilitating thermal conduction from the package structure PKG to the heat sink 470.

Reference is made to FIG. 7J. FIG. 7J illustrates a cross-sectional view of a package 510 corresponding to FIGS. 7E-7G in accordance with some embodiments of the present disclosure. While FIG. 7J illustrates embodiments of the package 510 with a different heat sink configuration than the package 210 in FIGS. 7E-7G, the present disclosure may repeat reference numerals and/or letters in the various examples. This repetition is for the purpose of simplicity and clarity and does not in itself dictate a relationship between the various embodiments and/or configurations discussed.

As shown in FIG. 7J, the difference between the embodiment in FIG. 7J and the embodiment in FIGS. 7E-7G is in that while the heat sink 570 retains a cover portion 70c and fin portions 70f, akin to the previous embodiment, it eliminates the protruding portions 270p1 and 270p2 that protrude beyond the back-side of cover portion 270c present in the previous embodiment. Specifically, trenches 570t1 and 570t2 can be formed within the cover portion 70c of the heat sink 570 and target areas within the package structure PKG that are less involved in heat generation. Specifically, the trench 570t1 can be positioned to align with the molding compound 52, while the trench 570t2 can be positioned to align with the underfill 54, nestled between the package components 46A and 46B. In some embodiments, the trench 570t1 can be with a ring-shaped footprint, encircling the areas of the package. The trenches 570t1 and 570t2 can have their own depths H4 and H3, respectively. In some embodiments, the depth H3 of trench 570t2 can be equal to or greater than the depth H4 of trench 570t1. In some embodiments, the depth H3 of trench 570t2 can be less than the depth H4 of trench 570t1. This gradation in dimensions can ensure a tailored fit and optimized thermal pathway within the heat sink 570, allowing for efficient heat dissipation.

On the other hand, the trenches 570t1 and 570t2 can define protruding portions 570p1 and 570p2 extending from the back-side of the cover portion 70c. Specifically, contours of the protruding portions 570p1 and 570p2 can be aligned with the geometries of the package components 46A and 46B within the package structure PKG. In some embodiments, the spatial footprint of package component 46A can fit within the boundary of protruding portion 570p1, and similarly, the footprint of package component 46B can fit within the boundary of protruding portion 570p2.

Reference is made to FIG. 7K. FIG. 7K illustrates a cross-sectional view of a package 610 corresponding to FIGS. 1-7D in accordance with some embodiments of the present disclosure. While FIG. 7K illustrates embodiments of the package 610 with a different heat sink configuration than the package 10 in FIGS. 1-7D, the present disclosure may repeat reference numerals and/or letters in the various examples. This repetition is for the purpose of simplicity and clarity and does not in itself dictate a relationship between the various embodiments and/or configurations discussed.

As shown in FIG. 7K, the difference between the embodiment in FIG. 7K and the embodiment in FIGS. 1-7D is in that while the heat sink 670 retains a cover portion 70c and fin portions 70f, akin to the previous embodiment, it eliminates the protruding portion 70p present in the previous embodiment and introduces a recessed portion 670r that overlays the package structure PKG. Specifically, after positioning the heat sink 70 and the conductive layer BSM2 atop the TIM layer 69, the recessed portion 670r can accommodate at least a part of the TIM layer 69, ensuring that the top surface of the TIM layer 69 is situated at a higher level than the surface S4 of the cover portion 70c. The recessed portion 670r can ensure direct contact between top surface of the TIM layer 69 and the heat sink 670, improving the thermal transfer efficiency from the semiconductor package to the heat sink 670. In some embodiments, side surfaces of the TIM layer 69 can contact a side surface of the recessed portion 670r in the heat sink 670 to further increase thermal contact. Additionally, embedding the TIM layer 69 within the recessed portion 670r can provide additional mechanical stability to the assembly, maintaining the integrity of the thermal interface under various operational conditions, including thermal cycling and mechanical stresses.

Reference is made to FIG. 7L. FIG. 7L illustrates a cross-sectional view of a package 710 corresponding to FIGS. 7E-7G in accordance with some embodiments of the present disclosure. While FIG. 7L illustrates embodiments of the package 710 with a different heat sink configuration than the package 10 in FIGS. 7E-7G, the present disclosure may repeat reference numerals and/or letters in the various examples. This repetition is for the purpose of simplicity and clarity and does not in itself dictate a relationship between the various embodiments and/or configurations discussed.

As shown in FIG. 7L, the difference between the embodiment in FIG. 7L and the embodiment in FIGS. 7E-7G is in that while the heat sink 770 retains a cover portion 70c and fin portions 70f, akin to the previous embodiment, it eliminates the protruding portions 270p1 and 270p2 that protrude beyond the back-side of cover portion 270c present in the previous embodiment and introduces a recessed portion 770r that overlays the package structure PKG. Specifically, after positioning the heat sink 70 and the conductive layer BSM2 atop the TIM layer 69, the recessed portion 770r can accommodate at least a part of the TIM layer 69, ensuring that the top surface of the TIM layer 69 is situated at a higher level than the surface S4 of the cover portion 70c. The recessed portion 770r can ensure direct contact between top surface and sidewalls of the TIM layer 69 and the heat sink 670, improving the thermal transfer efficiency from the semiconductor package to the heat sink 670. Additionally, embedding the TIM layer 69 within the recessed portion 770r can provide additional mechanical stability to the assembly, maintaining the integrity of the thermal interface under various operational conditions, including thermal cycling and mechanical stresses.

Specifically, trenches 770t1 and 770t2 can be formed within the cover portion 70c of the heat sink 770 and target areas within the package structure PKG that are less involved in heat generation. Specifically, the trench 770t1 can be positioned to align with the molding compound 52, while the trench 770t2 can be positioned to align with the underfill 54, nestled between the package components 46A and 46B. In some embodiments, the trench 770t1 can be with a ring-shaped footprint, encircling the areas of the package. The trenches 770t1 and 770t2 can have their own depths H6 and H5, respectively. In some embodiments, the depth H5 of trench 770t2 can be equal to or greater than the depth H6 of trench 770t1. In some embodiments, the depth H5 of trench 770t2 can be less than the depth H6 of trench 770t1. This gradation in dimensions can ensure a tailored fit and optimized thermal pathway within the heat sink 770, allowing for efficient heat dissipation.

On the other hand, the trenches 770t1 and 770t2 can define protruding portions 770p1 and 770p2 extending from the back-side of the cover portion 70c. Specifically, contours of the protruding portions 770p1 and 770p2 can be aligned with the geometries of the package components 46A and 46B within the package structure PKG. In some embodiments, the spatial footprint of package component 46A can fit within the boundary of protruding portion 770p1, and similarly, the footprint of package component 46B can fit within the boundary of protruding portion 770p2.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method by incorporating backside metallization (BSM) on both the CoW and heat sink, and employing a ring structure instead of a lid, the number of thermal interfaces can be reduced, which in turn decreases thermal resistance, leading to enhanced thermal performance. Additionally, incorporating a metal thermal interface material (metal TIM) directly bonded to the heat sink can avoid the issues of remelting during reflow processes that can affect thermal interface material coverage and performance. Furthermore, the ball grid array (BGA) package with metal thermal interface material can offers a smaller volume and greater I/O capabilities compared to land grid array (LGA) package, facilitating better system integration.

In some embodiments, a method includes bonding a package structure to a substrate; attaching a ring structure on the substrate and surrounding the package structure; forming a thermal interface material (TIM) layer over the package structure; attaching a heat sink structure to the TIM layer and the ring structure, in which the heat sink comprises a cover portion and a plurality of heat dissipating fins upwardly extending from a top surface of the cover portion. In some embodiments, the method further includes forming a metallization layer over the heat sink structure, wherein the heat sink structure is attached to the TIM layer through the metallization layer. In some embodiments, the metallization layer comprises aluminum (Al), titanium (Ti), nickel (Ni), vanadium (V), tantalum (Ta), silver (Ag), gold (Au), or combinations thereof. In some embodiments, the metallization layer has a thickness in a range from about 10 Å to 10000 Å. In some embodiments, the method further includes after attaching the heat sink structure, forming an intermetallic compound layer sandwiched between the metallization layer and the heat sink structure. In some embodiments, the intermetallic compound layer comprises a gold-indium alloy, a nickel-indium alloy, a nickel-gold-indium alloy, or combinations thereof. In some embodiments, the intermetallic compound layer has a thickness in a vertical range from about 0.1 to 2 μm. In some embodiments, the heat sink structure comprises copper, aluminum, or a combination thereof. In some embodiments, the method further includes bonding a surface mount device (SMD) to the substrate; conformally forming a protection coating on the SMD. In some embodiments, the protection coating comprises acrylic, epoxy, or a combination thereof.

In some embodiments, a method includes performing a backside metallization process over a package to form a first metallization layer on the package; placing the package onto an interposer; forming a thermal interface material (TIM) over the first metallization layer; forming a second metallization layer on a heat sink structure; attaching the heat sink structure to the TIM through the second metallization layer. In some embodiments, the heat sink structure has a stepped structure protruding from a bottom surface thereof, and the second metallization layer is formed on the stepped structure. In some embodiments, the heat sink structure has a flat bottom surface, and the second metallization layer is formed on the flat bottom surface. In some embodiments, the method further includes before attaching the heat sink structure, placing a ring structure onto the interposer to surround the package. In some embodiments, the TIM comprises indium.

In some embodiments, the package includes a package component, a thermal interface material (TIM) layer, a ring structure, and a heat sink structure. The package component is over a substrate. The package component includes a first device die, a second device die, and a molding compound laterally surrounding the first and second device dies. The thermal interface material (TIM) layer is over the package component. The ring structure is over the substrate and surrounds the package component. The heat sink is over the ring structure and the TIM layer. The heat sink includes a cover portion, heat dissipating fins upwardly extending from a top surface of the cover portion, and first and second protruding portions downwardly extending from a bottom surface of the cover portion. The first protruding portion has a first footprint overlapping with the first die, and the second protruding portion has a second footprint overlapping with the second die. In some embodiments, the first and second protruding portions downwardly extending beyond the bottom surface of the cover portion. In some embodiments, the package further includes an intermetallic compound layer between the TIM layer and the first protruding portion of the heat sink. In some embodiments, the ring structure comprises stainless, copper, or a combination thereof. In some embodiments, the package further includes a surface mount device (SMD) and a polymer-based coating. The SMD is over the substrate. The polymer-based coating is conformally formed on the SMD.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
bonding a package structure to a substrate;
attaching a ring structure on the substrate and surrounding the package structure;
forming a thermal interface material (TIM) layer over the package structure; and
attaching a heat sink structure to the TIM layer and the ring structure, wherein the heat sink structure comprises a cover portion and a plurality of heat dissipating fins upwardly extending from a top surface of the cover portion.

2. The method of claim 1, further comprising:
forming a metallization layer over the heat sink structure, wherein the heat sink structure is attached to the TIM layer through the metallization layer.

3. The method of claim 2, wherein the metallization layer comprises aluminum (Al), titanium (Ti), nickel (Ni), vanadium (V), tantalum (Ta), silver (Ag), gold (Au), or combinations thereof.

4. The method of claim 2, wherein the metallization layer has a thickness in a range from about 10 Å to 10000 Å.

5. The method of claim 2, further comprising:
after attaching the heat sink structure, forming an intermetallic compound layer sandwiched between the metallization layer and the heat sink structure.

6. The method of claim 5, wherein the intermetallic compound layer comprises a gold-indium alloy, a nickel-indium alloy, a nickel-gold-indium alloy, or combinations thereof.

7. The method of claim 5, wherein the intermetallic compound layer has a thickness in a vertical range from about 0.1 to 2 μm.

8. The method of claim 1, wherein the heat sink structure comprises copper, aluminum, or a combination thereof.

9. The method of claim 1, further comprising:
bonding a surface mount device (SMD) to the substrate; and
conformally forming a protection coating on the SMD.

10. The method of claim 9, wherein the protection coating comprises acrylic, epoxy, or a combination thereof.

11. A method, comprising:
performing a backside metallization process over a package to form a first metallization layer on the package;
placing the package onto an interposer;
forming a thermal interface material (TIM) over the first metallization layer;
forming a second metallization layer on a heat sink structure; and
attaching the heat sink structure to the TIM through the second metallization layer.

12. The method of claim 11, wherein the heat sink structure has a stepped structure protruding from a bottom surface thereof, and the second metallization layer is formed on the stepped structure.

13. The method of claim 11, wherein the heat sink structure has a flat bottom surface, and the second metallization layer is formed on the flat bottom surface.

14. The method of claim 11, further comprising:
before attaching the heat sink structure, placing a ring structure onto the interposer to surround the package.

15. The method of claim 11, wherein the TIM comprises indium.

16. A package, comprising:
a package component over a substrate, the package component comprising a first device die, a second device die, and a molding compound laterally surrounding the first and second device dies;
a thermal interface material (TIM) layer over the package component,
a ring structure over the substrate and surrounding the package component; and
a heat sink over the ring structure and the TIM layer, the heat sink comprising a cover portion, a plurality of heat dissipating fins upwardly extending from a top surface of the cover portion, and first and second protruding portions downwardly extending from a bottom surface of the cover portion, wherein the first protruding portion has a first footprint overlapping with the first device die, and the second protruding portion has a second footprint overlapping with the second device die.

17. The package of claim 16, wherein the first and second protruding portions downwardly extending beyond the bottom surface of the cover portion.

18. The package of claim 16, further comprising:
an intermetallic compound layer between the TIM layer and the first protruding portion of the heat sink.

19. The package of claim 16, wherein the ring structure comprises stainless, copper, or a combination thereof.

20. The package of claim 16, further comprising:
a surface mount device (SMD) over the substrate; and
a polymer-based coating conformally formed on the SMD.
